(19) United States
(12) Patent Application Publication
(10) Pub. No.: US 2023/0100576 A1
(43) Pub. Date: Mar. 30, 2023

(54) THICK AND THIN TRACES IN A BRIDGE WITH A GLASS CORE

(71) Applicant: Intel Corporation, Santa Clara, CA (US)

(72) Inventors: Andrew COLLINS, Chandler, AZ (US); Srinivas V. PIETAMBARAM, Chandler, AZ (US); Jianyong XIE, Chandler, AZ (US); Krishna Vasanth VALAVALA, Chandler, AZ (US)

(21) Appl. No.: 17/478,450

(22) Filed: Sep. 17, 2021

(51) Int. Cl. H05K 1/02; H05K 1/03; H05K 1/11; H05K 3/42

(52) U.S. Cl. CPC H05K 1/0224; H05K 1/112; H05K 1/0306; H05K 3/42

(57) ABSTRACT

Embodiments described herein may be related to apparatuses, processes, and techniques directed to bridges having a glass core, where the bridges may include one or more thick traces and one or more thin traces, where the thin traces are layered closer to a surface of the glass core, and the thick traces are layered further away from the glass core. During operation, the thin traces may be used to transmit signals between the coupled dies, and the thick traces may be used to transmit power between the coupled dies. During manufacture, the rigidity and highly planner surface of the glass core may enable thinner traces closer to the surface of the glass core to be placed with greater precision resulting in increased overall quality and robustness of transmitted signals. Other embodiments may be described and/or claimed.

### FIELD

Embodiments of the present disclosure generally relate to the field of semiconductor packaging, and in particular to bridges between dies within a package.

### BACKGROUND

Continued growth in computing and mobile devices will continue to increase the demand for increased bandwidth density between dies within semiconductor packages.

### BRIEF DESCRIPTION OF THE DRAWINGS

FIG. 1 includes block diagrams of side views of various package architectures with a bridge that couples one or more dies within a package, in accordance with various embodiments.

FIGS. 2A-2B illustrate a top-down and a side view of a block diagram of a bridge that couples multiple dies and includes multiple power domain power forwarding and signal paths through the bridge, in accordance with various embodiments.

FIG. 3 illustrates a cross-section view of a bridge with a glass core that includes thin traces next to the glass core and thicker traces away from the glass core, in accordance with various embodiments.

FIG. 4 illustrates a cross section view of a bridge with a glass core that includes an asymmetric thickness stack up on the sides of the glass core, in accordance with various embodiments.

FIG. 5 illustrates a cross section view of another bridge with a glass core that includes thin traces and thick traces on a side opposite the die attach side, in accordance with various embodiments.

FIG. 6 illustrates a cross-section view of another bridge with a glass core that includes asymmetric layer count but with asymmetric layer thickness in the stack up, in accordance with various embodiments.

FIG. 7 illustrates an example of a process for coupling an open cavity PIC with a thermal/power die, in accordance with various embodiments.

FIG. 8 illustrates multiple examples of laser-assisted etching of glass core processes, in accordance with embodiments.

FIG. 9 schematically illustrates a computing device, in accordance with various embodiments.

### DETAILED DESCRIPTION

Embodiments described herein may be related to apparatuses, processes, and techniques for bridges with a glass core that are used to couple multiple dies within a package. In embodiments, the bridges may include one or more thick traces and one or more thin traces within bills up layers on either side of the glass core, where the thin traces are layered closer to a surface of the glass core, and the thick traces are layered further away from the glass core. During operation, the thin traces may be used to transmit signals between the coupled dies, and the thick traces may be used to transmit power between the coupled dies. In embodiments, power forwarding from one die to the other may be implemented using these techniques.

In embodiments, the rigidity and highly planner surface of the glass core may enable thinner traces closer to the surface of the glass core to be placed with greater precision resulting in increased overall quality and robustness of signals over these thinner traces. Thicker traces that may support a higher level of current may be placed further away from the surface of the glass core. Multiple thicker traces within the bridge may be used to perform power forwarding, including power forwarding for multiple power domains.

In legacy implementations, distribution of on die power may be negatively impacted by die disaggregation package architectures. Robust power paths within die conductivity bridges or interposers may solve these legacy power challenges if these bridges can be patterned with both thick and thin metal layers, which may also be referred to as traces. A glass core within a bridge offers improved dimensional stability for fine pitch trace densities, which may also be referred to as wire densities, that are patterned near the glass plane.

In embodiments, the panel-based fabrication process may be capable of building thicker metal geometries that are used for power delivery on outer layers away from the surface of the glass core. Glass core-based via patterning may also be used for fine core pitch to enable multiple stack up and fabrication for die connectivity.

In legacy implementations, standard silicon-based bridge and interposer fabrication options do not offer metal thicknesses thick enough, for example 10-20 µm, for robust power distribution across metal shapes, that may include traces, planes or meshes within a metal layer. Through silicon vias (TSVs) can be used in legacy implementations to locally improve the vertical through bridge or silicon interposer power delivery path. However, the planar distribution of that power may still be problematic for the thin silicon wafer-based metal stacks.

In legacy implementations, the high resistance per millimeter squared (mm²) of silicon-based bridges/interposers can limit the die stacking configurations allowed by 3D package architectures based on power delivery sensitivity to high voltage drop. This becomes more problematic, especially when the depth of the input/output (I/O) physical layer (PHY) increases with tight specifications for both power delivery and I/O signaling. Low voltage power domains can enable a reduction in the current demand of a power rail, reducing the overall power consumption of that product. However, in legacy implementations, the increasing performance of high-speed, high bandwidth and longer channel length demands increasing power density and high current and voltage supply, which can result in higher product power consumption.

Embodiments of bridges or other structures described herein may include a variable metal thickness build-up, which may also be referred to as a stack-up, on a glass core substrate with thin inner metal layers and thick outer metal layers on either side of the glass core. These embodiments may include fine metal wire geometries enabled by the flat, uniform surface of the glass substrate for the inner metal layers that are used for performing die-to-die connectivity. The outer thicker metal layers may be placed using the high-density packaging panel-based processes available for patterning thick metal layers for power delivery.

Embodiments may facilitate, for both 2.5D and 3D packaging architectures, thick metal for planar power delivery distribution on high density interconnect within bridges and interposers. Embodiments may include power forwarding of IO power from one die, for example a transmitter die, to another die, for example a receiver die, across a die-to-die interface. Embodiments may also enable robust power delivery schemes for more generic applications, for example I/O bump encroachment over the glass core, by ensuring an even distribution of current under core power domains with a path for on-die capacitance (Cdie) sharing. Embodiments may enable reduced voltage drop to meet power delivery specifications, which may enable interface application for various signaling protocols with higher power/current and deeper I/O depth. Additionally, embodiments that include a thick metal layer and tight coupling between power and neighboring VSS power layers can further reduce the loop inductance, resulting less AC noise during package operation.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

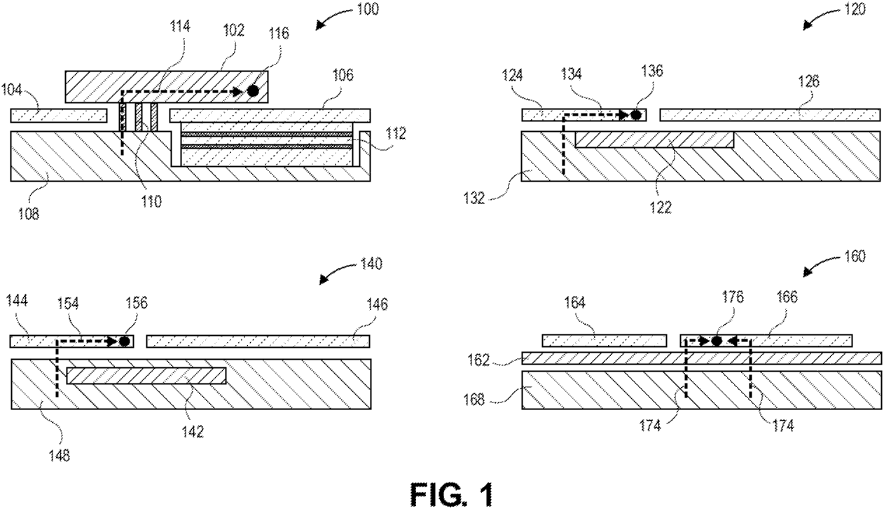

FIG. 1 includes block diagrams of side views of various package architectures with a bridge that couples one or more dies within a package, in accordance with various embodiments. Package 100 is an example of an Foveros omnidirectional I/O (ODI) with a top bridge channel communicating with a flipped high-bandwidth memory (HBM) die, package 120 is an example of an open cavity bridge (OCB), package 140 is an example of an embedded multi-die interconnect bridge (EMIB), package 160 is an example of a die complex on top of a passive interposer.

Package 100 is an example of an ODI package with a bridge 102 that is used to couple a first die 104 and a second die 106. The coupling may include electrical couplings that may route signals and/or power between the first die 104 and the second die 106. In embodiments, the bridge 102 may be electrically coupled with a substrate 108 using the electrical connections 110, for example to provide power to the bridge 102. In embodiments, the second die 106 may be coupled with or may be a part of a high-bandwidth memory 112 that is inverted and placed within a cavity in the substrate 108.

Package 120 is an example of an OCB. Bridge 122 is embedded within an open cavity within the substrate 132, and electrically couples a first die 124 with a second die 126. Package 140 is an example of an EMIB 142 coupled with the substrate 148, where the EMIB 142 electrically couples a first die 144 with a second die 146. EMIB 142 is embedded in a closed cavity within substrate 148. Package 160 is an example of a die complex on an interposer, where an interposer 162 is placed on top of a substrate 168, and couples a first die 164 with a second die 166.

Each of these examples, the bridge or interposer 102, 122, 142, 162 may not include a through via, such as a through silicon via (TSV), which may be used to provide power to the connecting dies. In embodiments where there is no TSV, then power traces, in legacy implementations, need to wrap all the way around the bridge. Embodiments described herein are directed to bridges and/or interposers that include thin metal layers for signaling and thick metal layers to direct power between dies and/or chips that are electrically coupled with the bridge or interposer.

In architectures where a bridge or interposer is utilized for die-to-die connectivity, efforts to continually scale down die interconnect pitch are reducing the effectiveness of thick on-die metal paths. On the thick on-die metal layers the power delivery paths share real estate with the off-die interconnect pad and via geometries. Reduced interconnect pitch reduces the area available for those power delivery paths resulting in a more resistive on-die power distribution.

Newer packaging architectures such as OCB 120 and ODI 100 can block power delivery paths in the die-to-die connectivity locations if a TSV is not used. Alternate new disaggregation architectures using legacy implementations can have long, in-plane power delivery paths where the current powering the dies must travel long distances from the current supply source, for example through package bumps, to the functional circuitry, for example a transmitter or receiver circuit.

For example, ODI package 100 with a flipped HBM die 112 may have a power routing flow distance along current supply source 114 to functional circuitry 116, that is on the order of 6-10 mm. OCB package 120 may have a power routing flow distance along current supply source 134 to functional circuitry 136 that is on the order of 1.5 mm or less. EMIB package 140 may have a have a power routing flow distance along current supply source 154 to functional circuity 156 that is on the order less than 2 mm, and package 160 of a die complex on a silicon interposer 160 may have a power routing flow distance along current supply sources 174 to functional circuitry 176 that is on the order of less than 0.3 mm. Standard ODI packages (not shown) may have a power routing flow distance on the order of 1 mm or less.

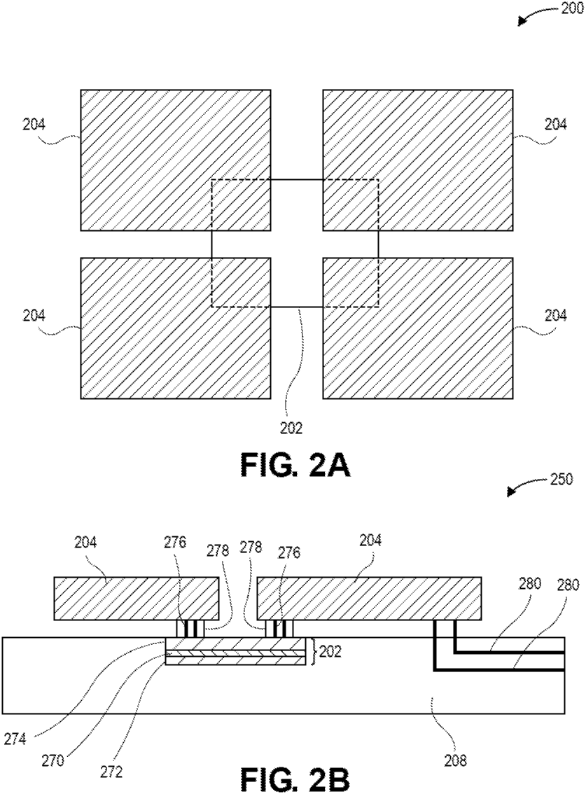

FIGS. 2A-2B illustrate a top-down and a side view of a block diagram of a bridge that couples multiple dies and includes multiple power domain power forwarding and signal paths through the bridge, in accordance with various embodiments. FIG. 2A illustrates a top-down view of a package 200 that includes a bridge 202, that may be similar to bridges 102, 122, 142, or may be similar to interposer 162 of FIG. 1. Multiple dies 204, which may be similar to dies 104, 106, 124, 126, 144, 146, 164, 166, are electrically coupled with the bridge 202 to allow electronic signals and/or power to be delivered between the multiple dies 204.

FIG. 2B illustrates a cross-section side view 250 of the package 200. Dies 204 are electrically coupled with the bridge 202 that includes a glass core 270 with a buildup layer 272 underneath the class core 270 and another buildup layer 274 above the glass core 270. In embodiments, the bridge 202 may be embedded within a substrate 208. Electrical traces within the package 200, discussed in greater detail below, are electrically coupled with the respective dies 204.

Thicker electrical contacts 276 between the bridge 202 and the dies 204 may be used to route current between the dies 204. Thinner electrical contacts 278 between the bridge 202 and the dies 204 may be used to route signals between the dies 204. In embodiments, one or more of the dies may receive power through one or more current flow paths 280 within the substrate 208. In embodiments is described further below, the power received from the one or more flow paths 280 may be forwarded between the dies 204 using the bridge 202.

Power delivery in high density die-to-die regions becomes more important when I/O power is forwarded from one die to another die across the bridge 202. In some cases, I/O interfaces may use a signal channel to share power from, for example, a transmit die to a receiver die across the signaling channel. Although this is important for noise isolation in high density die-to-die solutions to increase a timing margin, it requires a robust power delivery mesh on the bridge or interposer, in particular thicker electrical contacts 276. In embodiments, multiple power domains may be forwarded from one die to another die across the bridge 202.

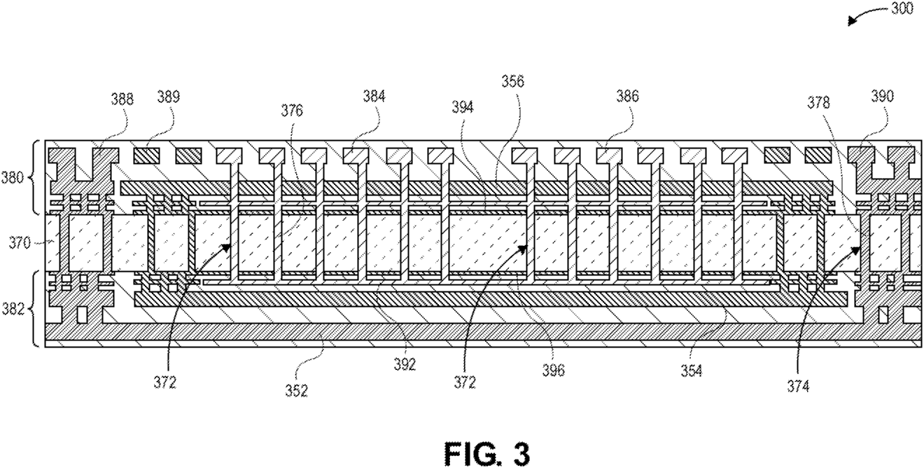

FIG. 3 illustrates a cross-section view of a bridge with a glass core that includes thin traces next to the glass core and thicker traces away from the glass core, in accordance with various embodiments. Bridge 300 may be similar to bridge 102, 122, 142, 162 of FIG. 1, or bridge 202 of FIGS. 2A-2B. Bridge 300 includes a glass core 370, which may be similar to glass core 270 of FIG. 2B, and may include one or more through glass vias (TGV) 372, 374 that extend from a first side of the glass core 370 to a second side of the glass core 370 opposite the first side. The TGV 372, 374 may be filled with a conductive material, such as copper, to create a conductive path 376, 378.

In embodiments, the pitch between the TGVs 372, 374 and therefore the conductive paths 376, 378, may be varied. For example, some conductive paths may be at a reduced pitch and/or may have a reduced through-hole diameters for transmitting signals, while other conductive paths may be at a larger pitch and/or may have greater through-hole diameters for conducting power.

In embodiments, a first buildup layer 380, which may be similar to buildup layer 274 of FIG. 2B, may be placed on a first side of the glass core 370, and a second buildup layer 382, which may be similar to buildup layer 272 of FIG. 2B, may be placed on the second side of the glass core 370 opposite the first side. In embodiments the first buildup layer 380 and the second buildup layer 382 may consist of multiple sublayers that include a combination of conductive material such as copper in the form of conductive traces or conductive pillars, or sublayers of dielectric to isolate the conductive material. In embodiments, the first buildup layer 380 and the second buildup layer 382 may have the same number of sublayers, which may referred to as being symmetric, or may have a different number of sublayers, which may be referred to as being asymmetric.

In embodiments, the thickness of each of the sublayers within the first buildup layer 380 and the second buildup layer 382 may be the same, or may be different. In embodiments, the first buildup layer 380 may have a same depth as a second buildup layer 382, while the first buildup layer 380 may have fewer sublayers than the second buildup layer 382, but each of the sublayers is thicker. In embodiments, the bridge 300 may have no first buildup layer 380, or may have no second buildup layer 382.

Bridge 300 may have a plurality of pads 384, 386, 388, 389, 390 to which a first die, such as die 104 and to which a second die, such as die 106 of FIG. 1, may be electrically and/or physically coupled. Some of the pads 384, 386 may be electrically coupled with thin traces 392, 394, 396 that are near the glass core 370 and may be used to carry electrical signals and associated return paths between the first die in the second die. Some of the pads 388, 389, 390 may be electrically coupled with thick traces 352, 354, 356 that may carry power to the first die and/or the second die, or to other dies to which the bridge 300 may be electrically coupled. In this way, on-die power distribution loads in dies such as dies 104, 106 may be supplemented by robust power paths within bridge 300.

The glass core 370 of the bridge 300 offers improved dimensional stability for fine pitch wire densities 392, 394, 396 that may be patterned near the glass plane. Panel-based fabrication processes capable of building thicker metal traces 352, 354, 356 may be used for power delivery on outer layers of the first buildup layer 380 and/or the second buildup layer 382. Note that bridge 300 shows individual sublayers within the first buildup layer 380, and the second buildup layer 382 as having a similar thickness and also having the same number of sublayers.

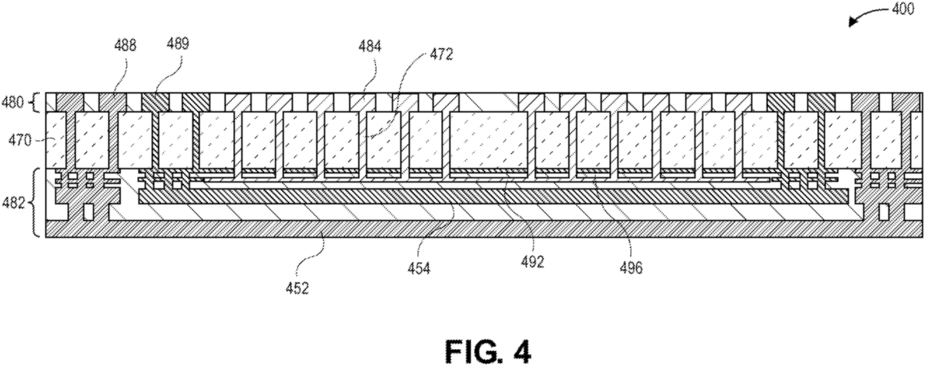

FIG. 4 illustrates a cross section view of a bridge with a glass core that includes an asymmetric thickness stack up on the sides of the glass core, in accordance with various embodiments. Bridge 400 includes a glass core 470, a first buildup layer 480 and a second buildup layer 482, which may be similar to glass core 370, first buildup layer 380 and second buildup layer 382 of FIG. 3. The first buildup layer 480 is thinner than the second buildup layer 482, and also has fewer sublayers. This configuration may be referred to as an asymmetric configuration.

The pitch of TGVs 472, which may be similar to TGV 372 of FIG. 3, may match an active die, such as die 204 of FIG. 2B, to be physically coupled directly onto the first buildup layer 480, and electrically coupled with the pads 484, 488, 489. In embodiments, signals may be routed through the thinner layers 492, 496 that are closest to the glass core 470, with power routed through the thicker layers 452, 454 that are further away from the glass core 470. In embodiments, this approach takes advantage of the tight pitches of the TGV 472 to route signals through the (bottom-side) buildup layer 482 without the signals having to pass through thick power delivery layers represented by traces 452, 454. Note the bottom-side thin, dense metal layers proximity adjacent to the glass core 470. The extremely flat glass core base is well suited for pattering thin, dense metal features for patterning the signal wires which would not be impacted by the thick out metal layers for power delivery.

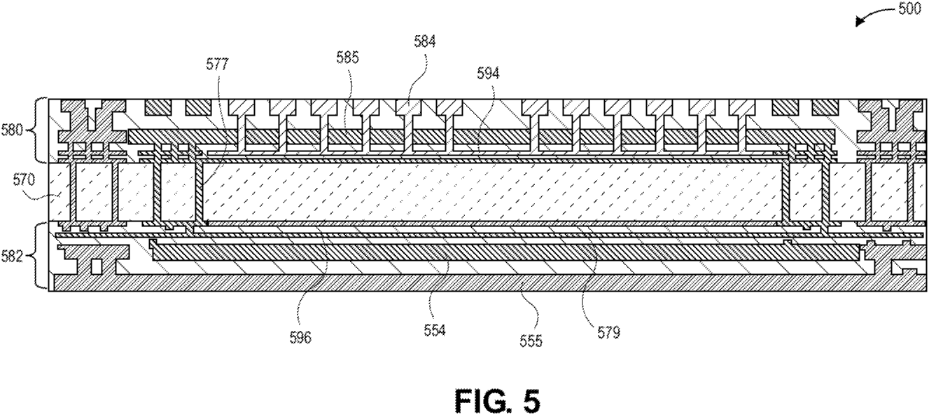

FIG. 5 illustrates a cross section view of another bridge with a glass core that includes thin traces and thick traces on a side opposite the die attach side, in accordance with various embodiments. Bridge 500, which may be similar to bridge 300 of FIG. 3, shows an embodiment of a symmetric first buildup layer 580 and a second buildup layer 582 on either sides of glass core 570. These may be similar to first buildup layer 380, second buildup layer 382, and glass core 370 of FIG. 3.

In bridge 500, the signal traces 594 do not pass through glass core at a tight pitch, similar to bridge 400, but rather are routed along the first buildup layer 580. This and similar embodiments may reduce the amount of cross talk experienced during operation by not routing the signals through the glass core with fine pitched TGVs. By relaxing the TGV fine pitch requirement, there is also more flexibility to modulate the glass core thickness for greater warpage control. Note that the various signal pads 584 may route through a thick VSS shielding layer 585, while power may be routed through the second buildup layer 582. In embodiments, the second buildup layer 582 may have multiple distribution paths, for example thinner traces 579, 596 that may be used as a low loop inductance AC power distribution path and the thicker outer traces 554, 555 may be used as a low resistance DC power path.

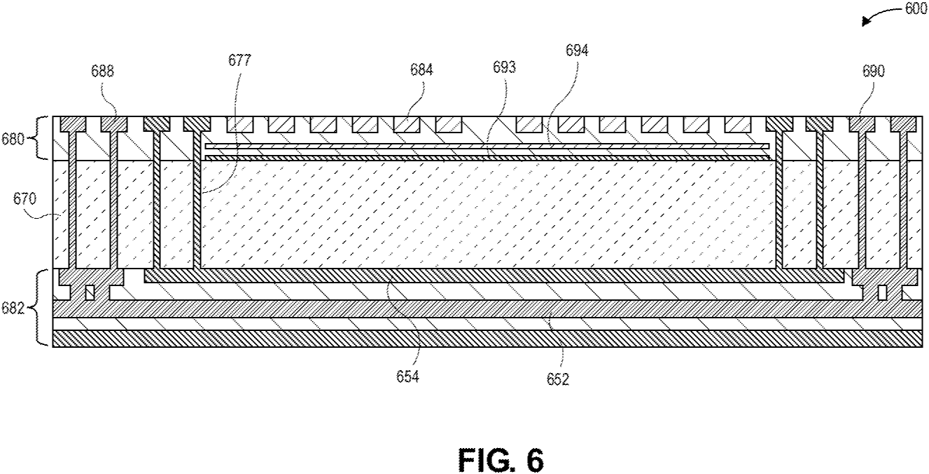

FIG. 6 illustrates a cross-section view of another bridge with a glass core that includes asymmetric layer count but with asymmetric layer thickness in the stack up, in accordance with various embodiments. Bridge 600, which may be similar to bridge 500 of FIG. 5, may have a first buildup layer 680 and a second buildup layer 682 on either side of the glass core 670. While there may be a same number of metal sublayers within the first buildup layer 680 and the second buildup layer 682, the thicknesses of the metal sublayers may not match. As shown, not having to match the metal thicknesses between the first buildup layer 680 and the second buildup layer 682 may result in a reduced metal layer count with characteristics of signal routing and power conductivity similar to bridge 500 of FIG. 5, bridge 400 of FIG. 4, and/or bridge 300 of FIG. 3 described herein.

For bridge 600, the pads 684, 688, 690 may couple electrically and/or physically with a die, such as die 204 of FIG. 2B. Signals may be routed using thin traces 693, 694 that are within the first buildup layer 680 and are close to the glass core 670. In embodiments, power routing may occur through thicker traces 652, 654 within the second buildup layer 682. As a result, signals may avoid using the TGV 677 and the cross talk impact of that signal path. In addition, this enables a low metal layer count for the bridge 600

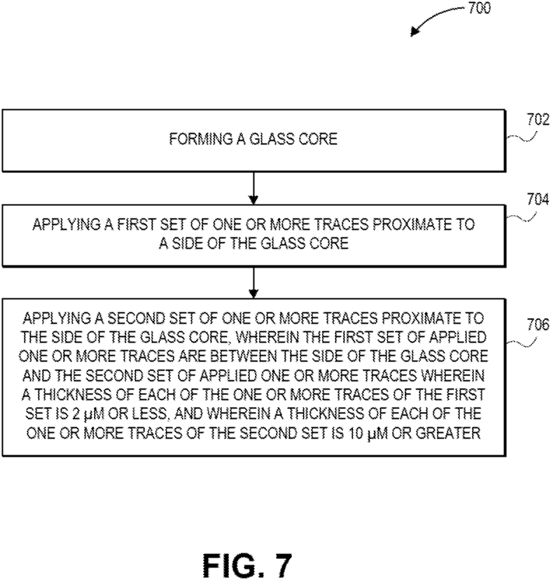

FIG. 7 illustrates an example of a process for coupling an open cavity PIC with a thermal/power die, in accordance with various embodiments. Process 700 may be performed using the techniques, methods, systems, processes, and/or apparatus as described with respect to FIGS. 1-6.

At block 702, the process may include forming a glass core. In embodiments, the glass core may be similar to glass core 370 of FIG. 3, 470 of FIG. 4, 570 of FIG. 5, and/or 670 of FIG. 6.

At block 704, the process may further include applying a first set of one or more traces proximate to a side of the glass core. In embodiments, the first set of one or more traces proximate to a side of the glass core may include traces 394, 396 of FIG. 3, traces 492, 496 of FIG. 4, traces 594, 579, 596 of FIG. 5, and/or traces 693, 694 of FIG. 6.

At block 706, the process may further include applying a second set of one or more traces proximate to the side of the glass core, wherein the first set of applied one or more traces are between the side of the glass core and the second set of applied one or more traces, and wherein a thickness of each of the one or more traces of the first set is 2 µm or less, and wherein a thickness of each of the one or more traces of the second set is 10 µm or greater. in embodiments, the second set of one or more traces may include traces 352, 354 of FIG. 3, traces 452, 454 of FIG. 4, traces 554, 555 of FIG. 5, and/or traces 652, 654 of FIG. 6.

In embodiments, the first set of the one or more traces and the second set of the one or more traces may be found within a first buildup layer and/or a second buildup layer. Examples of the first buildup layer may include first buildup layer 380 of FIG. 3, 480 of FIG. 4, 580 of FIG. 5, and/or 680 of FIG. 6. Examples of the second buildup layer may include second buildup layer 382 of FIG. 3, 482 of FIG. 4, 582 of FIG. 5, and/or 682 of FIG. 6.

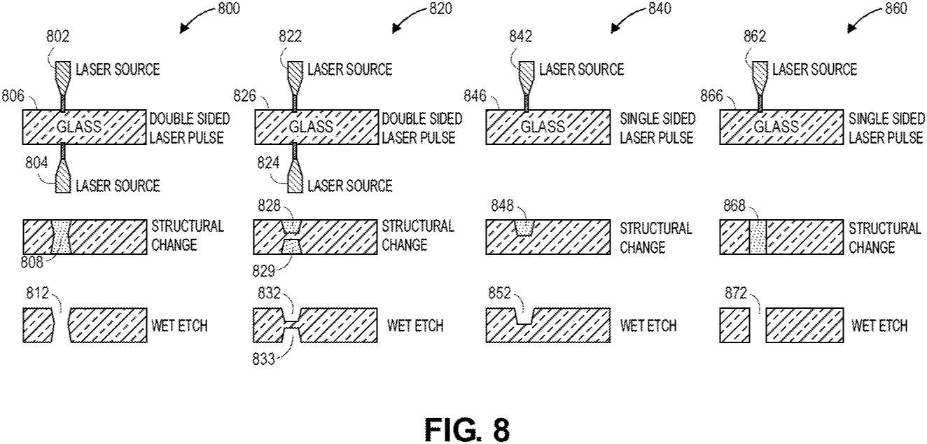

FIG. 8 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 800 shows a high-level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 812 is created by laser pulses from two laser sources 802, 804 on opposite sides of a glass wafer 806. As used herein, a through drill and a through via refers to when the drill or the via starts on one side of the glass/substrate and ends on the other side. A blind drill and a blind via refers to when the drill or the via starts on the surface of the substrate and stops halfway inside the substrate. In embodiments, the laser pulses from the two laser sources 802, 804 are applied perpendicularly to the glass wafer 806 to induce a morphological change 808, which may also be referred to as a structural change, in the glass that encounters the laser pulses. This morphological change 808 includes changes in the molecular structure of the glass to make it easier to etch out (remove a portion of the glass). In embodiments, a wet etch process may be used.

Diagram 820 shows a high level process flow for a double blind shape. A double blind shape 832, 833 may be created by laser pulses from two laser sources 822, 824, which may be similar to laser sources 802, 804, that are on opposite sides of the glass wafer 826, which may be similar to glass wafer 806. In this example, adjustments may be made in the laser pulse energy and/or the laser pulse exposure time from the two laser sources 822, 824. As a result, morphological changes 828, 829 in the glass 826 may result, with these changes making it easier to etch out portions of the glass. In embodiments, a wet etch process may be used.

Diagram 840 shows a high level process flow for a single-blind shape, which may also be referred to as a trench. In this example, a single laser source 842 delivers a laser pulse to the glass wafer 846 to create a morphological change 848 in the glass 846. As described above, these morphological changes make it easier to etch out a portion of the glass 852. In embodiments, a wet etch process may be used.

Diagram 860 shows a high level process flow for a through via shape. In this example, a single laser source 862 applies a laser pulse to the glass 866 to create a morphological change 868 in the glass 866, with the change making it easier to etch out a portion of the glass 872. As shown here, the laser pulse energy and/or laser pulse exposure time from the laser source 862 has been adjusted to create an etched out portion 872 that extends entirely through the glass 866.

With respect to FIG. 8, although embodiments show laser sources 802, 804, 822, 824, 842, 862 as perpendicular to a surface of the glass 806, 826, 846, 866, in embodiments, the laser sources may be positioned at an angle to the surface of the glass, with pulse energy and/or pulse exposure time variations in order to cause a diagonal via or a trench, or to shape the via, such as 812, 872, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 8, through hole vias 812, 872 may be created that are less than 10 µm in diameter, and may have an aspect ratio of 40:1 to 50:1. As a result, a far higher density of vias may be placed within the glass and be placed closer to each other at a fine pitch. In embodiments, this pitch may be 50 µm or less. After creating the vias or trenches, a metallization process may be applied in order to create a conductive pathway through the vias or trenches, for example a plated through hole (PTH). Using these techniques, finer pitch vias may result in better signaling, allowing more I/O signals to be routed through the glass wafer and to other coupled components such as a substrate.

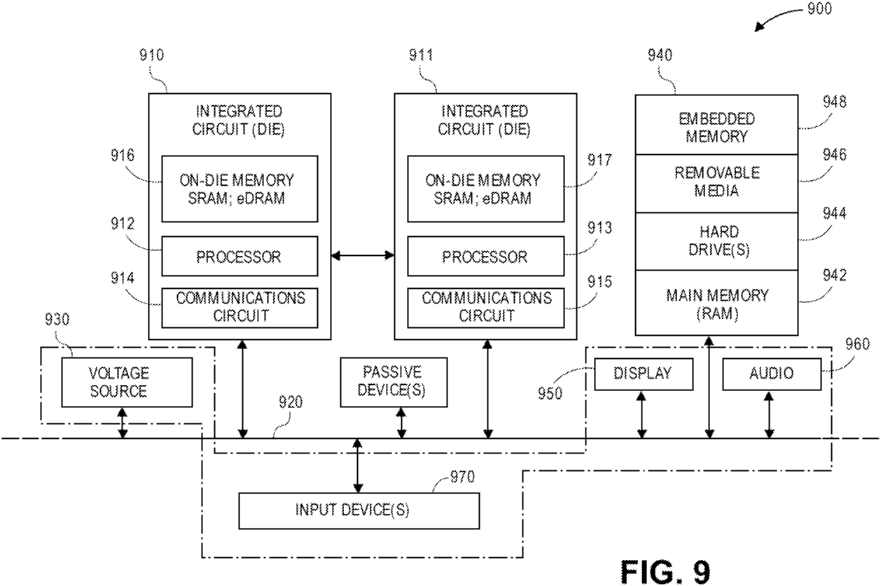

FIG. 9 is a schematic of a computer system 900, in accordance with an embodiment of the present invention. The computer system 900 (also referred to as the electronic system 900) as depicted can embody thick and thin traces in a bridge with a glass core, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 90. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, thick and thin traces in a bridge with a glass core, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having thick and thin traces in a bridge with a glass core, according to any of the several disclosed embodiments and their equivalents, an electronic system, a computer system, one or more methods of fabricating an integrated circuit, and one or more methods of fabricating an electronic assembly that includes a package substrate having thick and thin traces in a bridge with a glass core, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having thick and thin traces in a bridge with a glass core embodiments and their equivalents. A foundation substrate may be included, as represented by the dashed line of FIG. 9. Passive devices may also be included, as is also depicted in FIG. 9.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### Examples

Example 1 is an apparatus comprising: a glass core; a first set of one or more traces proximate to a side of the glass core; a second set of one or more traces proximate to the side of the glass core, wherein the first set of the one or more traces are between the side of the glass core and the second set of the one or more traces; and wherein a thickness of each of the one or more traces of the first set is less than a thickness of each of the one or more traces of the second set.

Example 2 includes the apparatus of example 1, wherein at least one of the one or more traces of the first set carry a selected one of an input output (I/O) signal or a ground during operation of the apparatus.

Example 3 includes the apparatus of example 1, wherein at least one of the one or more traces of the second set of carry a selected one of a ground or power during operation of the apparatus.

Example 4 includes the apparatus of example 3, wherein at least one of the one or more traces of the second set are associated with a first power domain, and wherein at least another of the one or more traces of the second set of the one or more traces are associated with a second power domain.

Example 5 includes the apparatus of example 1, wherein at least one trace of the first set of the one or more traces is directly physically coupled with the side of the glass core.

Example 6 includes the apparatus of example 1, further comprising a dielectric layer electrically separating the first set of the one or more traces and the second set of the one or more traces.

Example 7 includes the apparatus of example 1, wherein the first set of the one or more traces and the second set of the one or more traces are included within a buildup layer coupled with the side of the glass core.

Example 8 includes the apparatus of any one of examples 1-7, wherein the side of the glass core is a first side of the glass core, and further comprising: a second side of the glass core opposite the first side of the glass core; one or more through glass vias (TGV) extending from the first side of the glass core to the second side of the glass core, the one or more TGV including an electrically conductive material; one or more pads coupled with the second side of the glass core, the one or more pads electrically coupled, respectively, with the electrically conductive material of the one or more TGV; and wherein the electrically conductive material of the one or more TGV are electrically coupled with one or more traces of the first set of traces or with one or more traces of the second set of traces.

Example 9 includes the apparatus of example 8, further comprising a trace proximate to the second side of the glass core, wherein the electrically conductive material of the one or more TGV are electrically coupled with the trace proximate to the second side of the glass core.

Example 10 includes the apparatus of example 9, wherein the trace proximate to the second side of the glass core is directly physically coupled with the second side of the glass core.

Example 11 is a method comprising: forming a glass core; applying a first set of one or more traces proximate to a side of the glass core; applying a second set of one or more traces proximate to the side of the glass core, wherein the first set of applied one or more traces are between the side of the glass core and the second set of applied one or more traces; and wherein a thickness of each of the one or more traces of the first set is 2 µm or less, and wherein a thickness of each of the one or more traces of the second set is 10 µm or greater.

Example 12 includes the method of example 11, further comprising, before applying the second set of the one or more traces proximate to the side of the glass core, apply one or more layers of dielectric material on the first set of the one or more traces.

Example 13 includes the method of any one of examples 11-12, wherein the side of the glass core is a first side of the glass core; and wherein forming the glass core further comprises: forming one or more through glass vias (TGV) extending from the first side of the glass core to the second side of the glass core opposite the first side of the glass core; and filling or plating the one or more formed TGV with an electrically conductive material.

Example 14 includes the method of example 13, further comprising electrically coupling a selected TGV filled with the electrically conductive material with at least one of the one or more traces of the first set or at least one of the one or more traces of the second set.

Example 15 is a package comprising: a bridge comprising: a glass core; a first set of one or more traces proximate to a first side of the glass core; a second set of one or more traces proximate to the first side of the glass core, wherein the first set of the one or more traces are between the side of the glass core and the second set of the one or more traces; wherein a thickness of each of the one or more traces of the first set is less than a thickness of each of the one or more traces of the second set; one or more through glass vias (TGV) extending from the first side of the glass core to a second side of the glass core opposite the first side of the glass core, the one or more TGV including an electrically conductive material; one or more pads coupled with the second side of the glass core, the one or more pads electrically coupled, respectively, with the electrically conductive material of the one or more TGV; and wherein the electrically conductive material of the one or more TGV are electrically coupled with one or more traces of the first set of traces or with one or more traces of the second set of traces; a first die electrically coupled with one of the one or more traces of the first set or with one of the one or more traces of the second set; and a second die electrically coupled with one of the one or more traces of the first set or with one of the one or more traces of the second set.

Example 16 includes the package of example 15, wherein the bridge further comprises a third set of one or more traces proximate to the second side of the glass core, at least one of the one or more traces of the third set are electrically coupled with the electrically conductive material of at least two TGV.

Example 17 includes the package of any one of examples 15-16, wherein the bridge further comprises a fourth set of one or more traces proximate to the second side of the glass core, wherein the third set of the one or more traces are between the second side of the glass core and the fourth set of the one or more traces, wherein a thickness of each of the one or more traces of the third set is less than a thickness of each of the one or more traces of fourth set.

Example 18 includes the package of example 17, wherein at least one of the one or more traces of the third set carry a selected one of: an input/output (I/O) signal or a ground during operation of the package.

Example 19 includes the package of example 17, wherein at least one of the one or more traces of the fourth set carry a selected one of: a ground or power, during operation of the package.

Example 20 includes the package of example 17, wherein the bridge further comprises one or more dielectric layers between the third set of the one or more traces and the fourth set of the one or more traces.

What is claimed is:

1. An apparatus comprising:
a glass core;
a first set of one or more traces proximate to a side of the glass core;
a second set of one or more traces proximate to the side of the glass core, wherein the first set of the one or more traces are between the side of the glass core and the second set of the one or more traces; and
wherein a thickness of each of the one or more traces of the first set is less than a thickness of each of the one or more traces of the second set.

2. The apparatus of claim 1, wherein at least one of the one or more traces of the first set carry a selected one of an input output (I/O) signal or a ground during operation of the apparatus.

3. The apparatus of claim 1, wherein at least one of the one or more traces of the second set of carry a selected one of a ground or power during operation of the apparatus.

4. The apparatus of claim 3, wherein at least one of the one or more traces of the second set are associated with a first power domain, and wherein at least another of the one or more traces of the second set of the one or more traces are associated with a second power domain.

5. The apparatus of claim 1, wherein at least one trace of the first set of the one or more traces is directly physically coupled with the side of the glass core.

6. The apparatus of claim 1, further comprising a dielectric layer electrically separating the first set of the one or more traces and the second set of the one or more traces.

7. The apparatus of claim 1, wherein the first set of the one or more traces and the second set of the one or more traces are included within a buildup layer coupled with the side of the glass core.

8. The apparatus of claim 1, wherein the side of the glass core is a first side of the glass core, and further comprising:
a second side of the glass core opposite the first side of the glass core;
one or more through glass vias (TGV) extending from the first side of the glass core to the second side of the glass core, the one or more TGV including an electrically conductive material;
one or more pads coupled with the second side of the glass core, the one or more pads electrically coupled, respectively, with the electrically conductive material of the one or more TGV; and
wherein the electrically conductive material of the one or more TGV are electrically coupled with one or more traces of the first set of traces or with one or more traces of the second set of traces.

9. The apparatus of claim 8, further comprising a trace proximate to the second side of the glass core, wherein the electrically conductive material of the one or more TGV are electrically coupled with the trace proximate to the second side of the glass core.

10. The apparatus of claim 9, wherein the trace proximate to the second side of the glass core is directly physically coupled with the second side of the glass core.

11. A method comprising:
forming a glass core;
applying a first set of one or more traces proximate to a side of the glass core;
applying a second set of one or more traces proximate to the side of the glass core, wherein the first set of applied one or more traces are between the side of the glass core and the second set of applied one or more traces; and
wherein a thickness of each of the one or more traces of the first set is 2 µm or less, and wherein a thickness of each of the one or more traces of the second set is 10 µm or greater.

12. The method of claim 11, further comprising, before applying the second set of the one or more traces proximate to the side of the glass core, apply one or more layers of dielectric material on the first set of the one or more traces.

13. The method of claim 11, wherein the side of the glass core is a first side of the glass core; and wherein forming the glass core further comprises:
forming one or more through glass vias (TGV) extending from the first side of the glass core to the second side of the glass core opposite the first side of the glass core; and
filling or plating the one or more formed TGV with an electrically conductive material.

14. The method of claim 13, further comprising electrically coupling a selected TGV filled with the electrically conductive material with at least one of the one or more traces of the first set or at least one of the one or more traces of the second set.

15. A package comprising:
a bridge comprising:
glass core;
a first set of one or more traces proximate to a first side of the glass core;
a second set of one or more traces proximate to the first side of the glass core, wherein the first set of the one or more traces are between the side of the glass core and the second set of the one or more traces;
wherein a thickness of each of the one or more traces of the first set is less than a thickness of each of the one or more traces of the second set;
one or more through glass vias (TGV) extending from the first side of the glass core to a second side of the glass core opposite the first side of the glass core, the one or more TGV including an electrically conductive material;
one or more pads coupled with the second side of the glass core, the one or more pads electrically coupled, respectively, with the electrically conductive material of the one or more TGV; and
wherein the electrically conductive material of the one or more TGV are electrically coupled with one or more traces of the first set of traces or with one or more traces of the second set of traces;
a first die electrically coupled with one of the one or more traces of the first set or with one of the one or more traces of the second set; and
a second die electrically coupled with one of the one or more traces of the first set or with one of the one or more traces of the second set.

16. The package of claim 15, wherein the bridge further comprises a third set of one or more traces proximate to the second side of the glass core, at least one of the one or more traces of the third set are electrically coupled with the electrically conductive material of at least two TGV.

17. The package of claim 16, wherein the bridge further comprises a fourth set of one or more traces proximate to the second side of the glass core, wherein the third set of the one or more traces are between the second side of the glass core and the fourth set of the one or more traces, wherein a thickness of each of the one or more traces of the third set is less than a thickness of each of the one or more traces of fourth set.

18. The package of claim 17, wherein at least one of the one or more traces of the third set carry a selected one of: an input/output (I/O) signal or a ground during operation of the package.

19. The package of claim 17, wherein at least one of the one or more traces of the fourth set carry a selected one of: a ground or power, during operation of the package.

20. The package of claim 17, wherein the bridge further comprises one or more dielectric layers between the third set of the one or more traces and the fourth set of the one or more traces.
